(19) United States
(12) Patent Application Publication
(10) Pub. No.: US 2009/0137112 A1
(43) Pub. Date: May 28, 2009

(54) METHOD OF MANUFACTURING NONVOLATILE SEMICONDUCTOR MEMORY DEVICES

(75) Inventors: Hideyuki TABATA, Kawasaki-shi (JP); Hirofumi Inoue, Kamakura-shi (JP); Hiroyuki Nagashima, Yokohama-shi (JP); Kohichi Kubo, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/275,741

(22) Filed: Nov. 21, 2008

(30) Foreign Application Priority Data
Nov. 22, 2007 (JP) 2007-303666

(51) Int. Cl. H01L 21/768

(52) U.S. Cl. 438/631; 438/622; 257/E21.583; 257/E21.575

(57) ABSTRACT

A method of manufacturing nonvolatile semiconductor memory devices comprises forming a first wiring material; and stacking memory cell materials on the first wiring material, which configure memory cells each including a variable resistor operative to nonvolatilely store information in accordance with variation in resistance. The method also comprises forming a plurality of first parallel trenches in the first wiring material and the stacked memory cell materials, the first trenches extending in a first direction, thereby forming first lines extending in the first direction and memory cell materials self-aligned with the first lines and separated by the first trenches. The method further comprises burying an interlayer insulator in the first trenches to form a block body and stacking a second wiring material on the block body. The method also comprises forming a plurality of second parallel trenches in the block body with the second wiring material stacked thereon, the second trenches extending in a second direction crossing the first direction and having a depth reaching the upper surface of the first wiring material, thereby forming second lines extending in the second direction and memory cells self-aligned with the second lines and separated by the first and second trenches.

### CROSS-REFERENCE TO RELATED APPLICATION

This application is based upon and claims the benefit of priority from the prior Japanese Patent Application No. 2007-303666, filed on Nov. 22, 2007, the entire contents of which are incorporated herein by reference.

### BACKGROUND OF THE INVENTION

1. Field of the Invention

The present invention relates to a method of manufacturing nonvolatile semiconductor devices comprising memory cells of the cross point type.

2. Description of the Related Art

Electrically erasable programmable nonvolatile memories include a flash memory as well known in the art, which comprises a memory cell array of NAND-connected or NOR-connected memory cells having a floating gate structure. A ferroelectric memory is also known as a nonvolatile fast random access memory.

On the other hand, technologies of pattering memory cells much finer include a resistance variable memory, which uses a variable resistor in a memory cell as proposed. Known examples of the variable resistor include a phase change memory element that varies the resistance in accordance with the variation in crystal/amorphous states of a chalcogenide compound; an MRAM element that uses a variation in resistance due to the tunnel magneto-resistance effect; a polymer ferroelectric RAM (PFRAM) memory element including resistors formed of a conductive polymer; and a ReRAM element that causes a variation in resistance on electrical pulse application (Patent Document 1: JP 2006-344349A, paragraph 0021).

The resistance variable memory may configure a memory cell with a serial circuit of a Schottky diode and a resistance variable element in place of the transistor. Accordingly, it can apply a cross point structure in which a memory cell is arranged at an intersection of upper and lower lines. Therefore, it can be formed easier and three-dimensionally structured to achieve much higher integration advantageously (Patent Document 2: JP 2005-522045A).

The above-described prior nonvolatile semiconductor memory device comprising memory cells of the cross point type leaves a stacked body block composed of memory cell materials in a pillar shape to form a memory cell. Therefore, the progression of fine patterning and highly integrating memory cells makes it difficult to align the upper and lower lines with the memory cells. The misalignment of the memory cell and the line increases the resistance of a connection portion between the memory cell and the line and lowers the operating margin as a problem.

### SUMMARY OF THE INVENTION

In an aspect the present invention provides a method of manufacturing nonvolatile semiconductor memory devices, comprising: forming a first wiring material; stacking memory cell materials on the first wiring material, which configure memory cells each including a variable resistor operative to nonvolatilely store information in accordance with a variation in resistance; forming a plurality of first parallel trenches in the first wiring material and the stacked memory cell materials, the first trenches extending in a first direction, thereby forming first lines extending in the first direction and memory cell materials self-aligned with the first lines and separated by the first trenches; burying an interlayer insulator in the first trenches to form a block body; stacking a second wiring material on the block body; and forming a plurality of second parallel trenches in the block body with the second wiring material stacked thereon, the second trenches extending in a second direction crossing the first direction and having a depth reaching the upper surface of the first wiring material, thereby forming second lines extending in the second direction and memory cells self-aligned with the second lines and separated by the first and second trenches.

In another aspect the present invention provides a method of manufacturing nonvolatile semiconductor memory devices, comprising: forming a first interlayer insulator on a semiconductor substrate; forming a first wiring material on the first interlayer insulator; stacking memory cell materials on the first wiring material, which configure memory cells each including a variable resistor operative to nonvolatilely store information in accordance with a variation resistance; forming a plurality of first parallel trenches in the first wiring material and the stacked memory cell materials, the first trenches extending in a first direction, thereby forming first lines extending in the first direction and memory cell materials self-aligned with the first lines and separated by the first trenches; burying a second interlayer insulator in the first trenches to form a block body and planarizing the surface of the block body to expose the memory cell materials; stacking a second wiring material on the planarized block body; forming a plurality of second parallel trenches in the block body with the second wiring material stacked thereon, the second trenches extending in a second direction crossing the first direction and having a depth reaching the upper surface of the first wiring material, thereby forming second lines extending in the second direction and memory cells self-aligned with the second lines and separated by the first and second trenches; and burying a third interlayer insulator in the second trenches.

In yet another aspect the present invention provides a method of manufacturing nonvolatile semiconductor memory devices, comprising: forming a first wiring material; sequentially depositing a layer turned into a barrier metal, a layer turned into a non-ohmic element, a layer turned into a first electrode, a layer turned into a variable resistor, and a layer turned into a second electrode as memory cell materials on the first wiring material; forming a plurality of first parallel trenches in the first wiring material and the stacked memory cell materials, the first trenches extending in a first direction, thereby forming first lines extending in the first direction and memory cell materials self-aligned with the first lines and separated by the first trenches; burying an interlayer insulator in the first trenches to form a block body; stacking a second wiring material on the block body; and forming a plurality of second parallel trenches in the block body with the second wiring material stacked thereon, the second trenches extending in a second direction crossing the first direction and having a depth reaching the upper surface of the first wiring material, thereby forming second lines extending in the second direction and memory cells self-aligned with the second lines and separated by the first and second trenches.

### BRIEF DESCRIPTION OF THE DRAWINGS

FIG. 1 is a block diagram of a nonvolatile memory according to a first embodiment of the present invention.

FIG. 2 is a perspective view of part of a memory cell array in the nonvolatile memory according to the same embodiment.

FIG. 3 is a cross-sectional view of one memory cell taken along I-I′ line and seen from the direction of the arrow in FIG. 2.

FIG. 4 is a schematic cross-sectional view showing a variable resistor example in the same embodiment.

FIG. 5 is a schematic cross-sectional view showing another variable resistor example in the same embodiment.

FIG. 6 is a schematic cross-sectional view showing a non-ohmic element example in the same embodiment.

FIG. 7 is a perspective view of part of a memory cell array according to another embodiment of the present invention.

FIG. 8 is a cross-sectional view of one memory cell taken along II-II′ line and seen from the direction of the arrow in FIG. 7.

FIG. 9 is a circuit diagram of the memory cell array and peripheral circuits thereof according to the same embodiment.

FIG. 10 is a cross-sectional view of the nonvolatile memory according to the same embodiment.

FIG. 11 is a perspective view showing a step of forming the upper layer portion in the nonvolatile memory according to the same embodiment in order of step.

FIG. 12 is a perspective view showing a step of forming the upper layer portion in the nonvolatile memory according to the same embodiment in order of step.

FIG. 13 is a perspective view showing a step of forming the upper layer portion in the nonvolatile memory according to the same embodiment in order of step.

FIG. 14 is a perspective view showing a step of forming the upper layer portion in the nonvolatile memory according to the same embodiment in order of step.

FIG. 15 is a perspective view showing a step of forming the upper layer portion in the nonvolatile memory according to the same embodiment in order of step.

FIG. 16 is a perspective view showing a step of forming the upper layer portion in the nonvolatile memory according to the same embodiment in order of step.

### DETAILED DESCRIPTION OF THE EMBODIMENTS

The embodiments of the invention will now be described with reference to the drawings.

### First Embodiment

### [Entire Configuration]

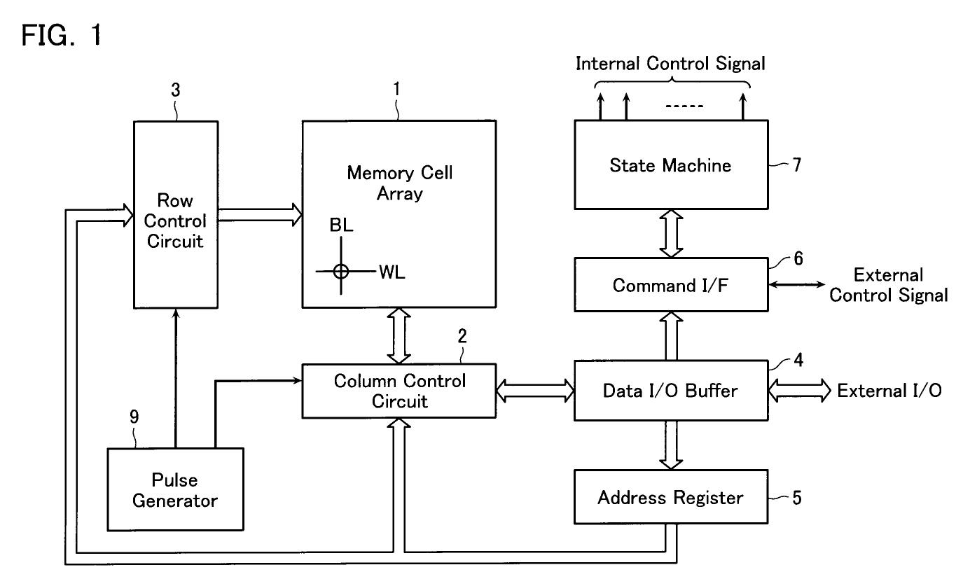

FIG. 1 is a block diagram of a nonvolatile memory according to a first embodiment of the present invention.

The nonvolatile memory comprises a memory cell array 1 of memory cells arranged in matrix, each memory cell including a later-described ReRAM (variable resistor). A column control circuit 2 is provided on a position adjacent to the memory cell array 1 in the bit line BL direction. It controls the bit line BL in the memory cell array 1 to erase data from the memory cell, write data in the memory cell, and read data out of the memory cell. A row control circuit 3 is provided on a position adjacent to the memory cell array 1 in the word line WL direction. It selects the word line WL in the memory cell array 1 and applies voltages required to erase data from the memory cell, write data in the memory cell, and read data out of the memory cell.

A data I/O buffer 4 is connected to an external host, not shown, via an I/O line to receive write data, receive erase instructions, provide read data, and receive address data and command data. The data I/O buffer 4 sends received write data to the column control circuit 2 and receives read-out data from the column control circuit 2 and provides it to external. An address fed from external to the data I/O buffer 4 is sent via an address register 5 to the column control circuit 2 and the row control circuit 3. A command fed from the host to the data I/O buffer 4 is sent to a command interface 6. The command interface 6 receives an external control signal from the host and decides whether the data fed to the data I/O buffer 4 is write data, a command or an address. If it is a command, then the command interface 6 transfers it as a received command signal to a state machine 7. The state machine 7 manages the entire nonvolatile memory to receive commands from the host to execute read, write, erase, and execute data I/O management. The external host can also receive status information managed by the state machine 7 and decides the operation result. The status information is also utilized in control of write and erase.

The state machine 7 controls the pulse generator 9. Under this control, the pulse generator 9 is allowed to provide a pulse of any voltage at any timing. The pulse formed herein can be transferred to any line selected by the column control circuit 2 and the row control circuit 3.

Peripheral circuit elements other than the memory cell array 1 can be formed in a Si substrate immediately beneath the memory cell array 1 formed in a wiring layer. Thus, the chip area of the nonvolatile memory can be made almost equal to the area of the memory cell array 1.

### [Memory Cell Array and Peripheral Circuits]

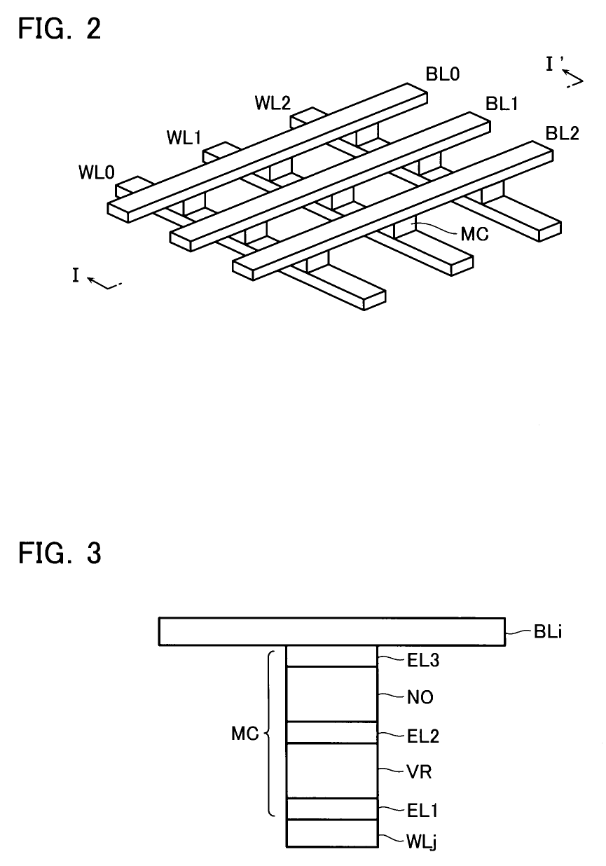

FIG. 2 is a perspective view of part of the memory cell array 1, and FIG. 3 is a cross-sectional view of one memory cell taken along I-I′ line and seen in the direction of the arrow in FIG. 2.

There are plural first lines or word lines WL0-WL2 disposed in parallel, which cross plural second lines orbit lines BL0-BL2 disposed in parallel. A memory cell MC is arranged at each intersection of both lines as sandwiched therebetween. Desirably, the first and second lines are composed of heat-resistive low-resistance material such as W, WSi, NiSi, CoSi.

The memory cell MC comprises a serial connection circuit of a variable resistor VR and a non-ohmic element NO as shown in FIG. 3.

The variable resistor VR can vary the resistance through current, heat, or chemical energy on voltage application.

Arranged on an upper and a lower surface thereof are electrodes EL1, EL2 serving as a barrier metal layer and an adhesive layer. Material of the electrodes may include Pt, Au, Ag, TiAlN, SrRuO, Ru, RuN, Ir, Co, Ti, TiN, TaN, LaNiO, Al, PtIrOx, PtRhOx, Rh/TaAlN. A metal film capable of achieving uniform orientation may also be interposed. A buffer layer, a barrier metal layer and an adhesive layer may further be interposed.

The variable resistor VR may include one that comprises a composite compound containing cations of a transition element and varies the resistance through migration of cations (ReRAM).

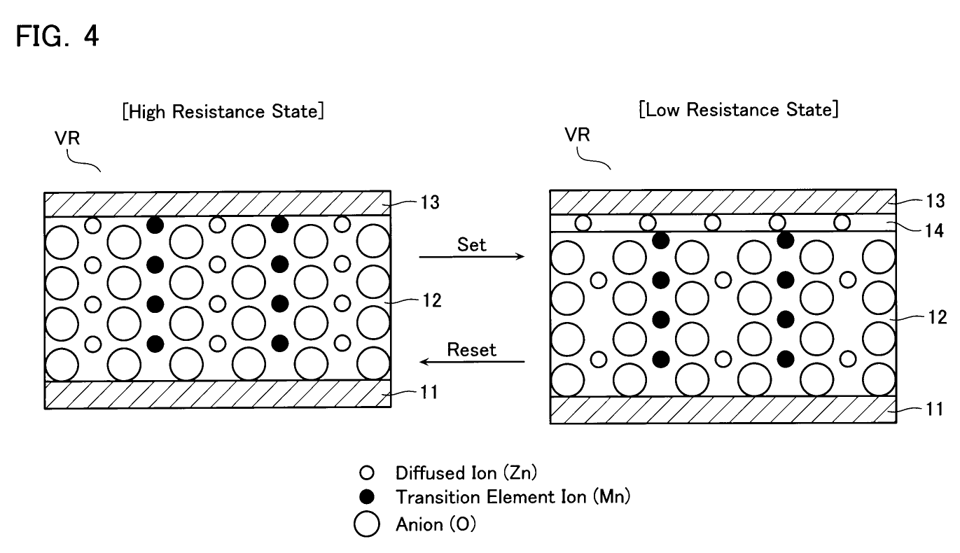

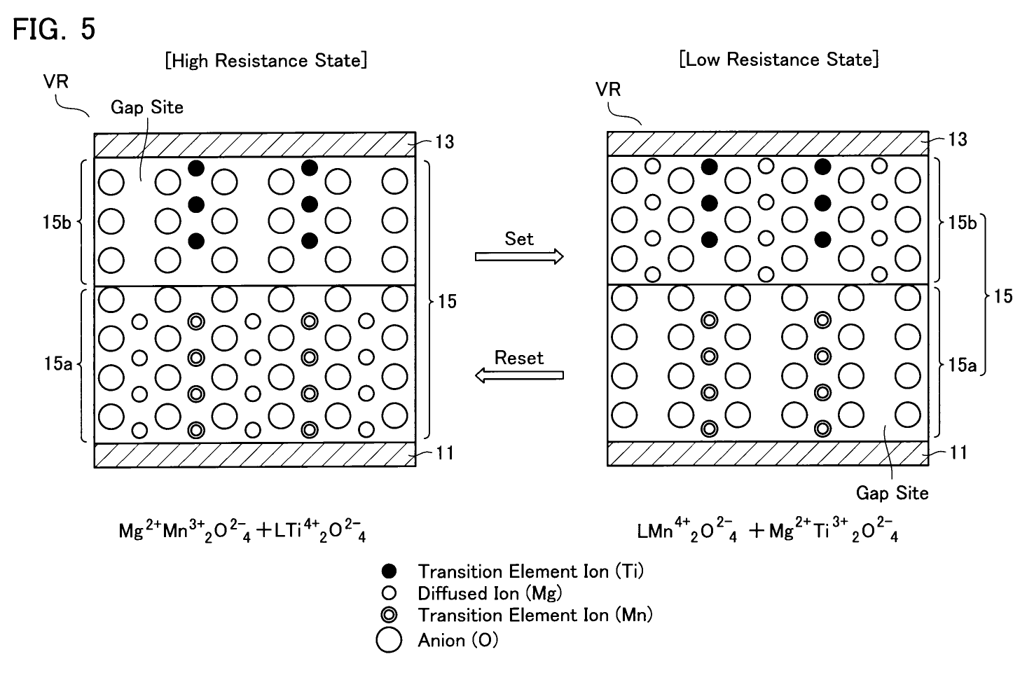

FIGS. 4 and 5 show examples of the variable resistor. The variable resistor VR shown in FIG. 4 includes a recording layer 12 arranged between electrode layers 11, 13. The recording layer 12 is composed of a composite compound containing at least two types of cation elements. At least one of the cation elements is a transition element having the d-orbit incompletely filled with electrons, and the shortest distance between adjacent cation elements is 0.32 nm or lower. Specifically, it is represented by a chemical formula AₓM_{y}X_{z} (A and M are different elements) and may be formed of material having a crystal structure such as a spinel structure (AM₂O₄), an ilmenite structure (AMO₃), a delafossite structure (AMO₂), a LiMoN₂ structure (AMN₂), a wolframite structure (AMO₄), an olivine structure (A₂MO₄), a hollandite structure (A₂MO₂), a ramsdellite structure (AₓMO₂), and a perovskite structure (AMO₃).

In the example of FIG. 4, A comprises Zn, M comprises Mn, and X comprises O. In the recording layer 12, a small white circle represents a diffused ion (Zn), a large white circle represents an anion (O), and a small black circle represents a transition element ion (Mn). The initial state of the recording layer 12 is the high-resistance state. When the electrode layer 11 is kept at a fixed potential and a negative voltage is applied to the electrode layer 13, part of diffused ions in the recording layer 12 migrate toward the electrode layer 13 to reduce diffused ions in the recording layer 12 relative to anions. The diffused ions arrived at the electrode layer 13 accept electrons from the electrode layer 13 and precipitate as a metal, thereby forming a metal layer 14. Inside the recording layer 12, anions become excessive and consequently increase the valence of the transition element ion in the recording layer 12. As a result, the carrier injection brings the recording layer 12 into electron conduction and thus completes setting. On data reading, a current may be allowed to flow, of which value is very small so that the material configuring the recording layer 12 causes no resistance variation. The programmed state (low-resistance state) may be reset to the initial state (high-resistance state) by supplying a large current flow in the recording layer 12 for a sufficient time, which causes Joule heating to facilitate the oxidation reduction reaction in the recording layer 12. Application of an electric field in the opposite direction from that at the time of setting may also allow resetting.

In the example of FIG. 5, a recording layer 15 sandwiched between the electrode layers 11, 13 is formed of two layers: a first compound layer 15a and a second compound layer 15b. The first compound layer 15a is arranged on the side close to the electrode layer 11 and represented by a chemical formula AₓM1_{y}X1_{z}. The second compound layer 15b is arranged on the side close to the electrode layer 13 and has gap sites capable of accommodating cation elements from the first compound layer 15a.

In the example of FIG. 5, A comprises Mg, M1 comprises Mn, and X1 comprises O in the first compound layer 15a. The second compound layer 15b contains Ti shown with black circles as transition element ions. In the first compound layer 15a, a small white circle represents a diffused ion (Mg), a large white circle represents an anion (O), and a double circle represents a transition element ion (Mn). The first compound layer 15a and the second compound layer 15b may be stacked in multiple layers such as two or more layers.

In such the variable resistor VR, potentials are given to the electrode layers 11, 13 so that the first compound layer 15a serves as an anode and the second compound layer 15b serves as a cathode to cause a potential gradient in the recording layer 15. In this case, part of diffused ions in the first compound layer 15a migrate through the crystal and enter the second compound layer 15b on the cathode side. The crystal of the second compound layer 15b includes gap sites capable of accommodating diffused ions. Accordingly, the diffused ions moved from the first compound layer 15a are trapped in the gap sites. Therefore, the valence of the transition element ion in the first compound layer 15a increases while the valence of the transition element ion in the second compound layer 15b decreases. In the initial state, the first and second compound layers 15a, 15b may be in the high-resistance state. In such the case, migration of part of diffused ions in the first compound layer 15a therefrom into the second compound layer 15b generates conduction carriers in the crystals of the first and second compounds, and thus both have electric conduction. The programmed state (low-resistance state) may be reset to the erased state (high-resistance state) by supplying a large current flow in the recording layer 15 for a sufficient time for Joule heating to facilitate the oxidation reduction reaction in the recording layer 15, like in the preceding example. Application of an electric field in the opposite direction from that at the time of setting may also allow reset.

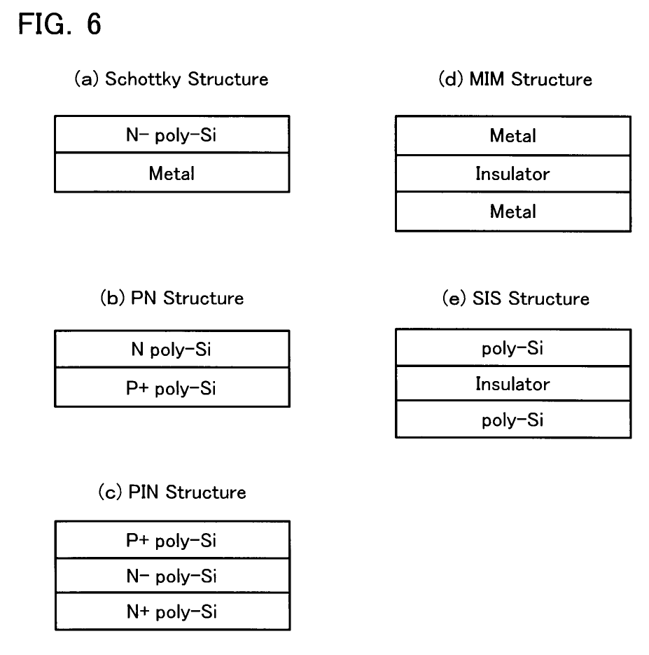

The non-ohmic element NO may include various diodes such as (a) a Schottky diode, (b) a PN-junction diode, (c) a PIN diode and may have (d) a MIM (Metal-Insulator-Metal) structure, and (e) a SIS (Silicon-Insulator-Silicon) structure as shown in FIG. 6. In this case, electrodes EL2, EL3 forming a barrier metal layer and an adhesive layer may be interposed. If a diode is used, from the property thereof, it can perform the unipolar operation. In the case of the MIM structure or SIS structure, it can perform the bipolar operation.

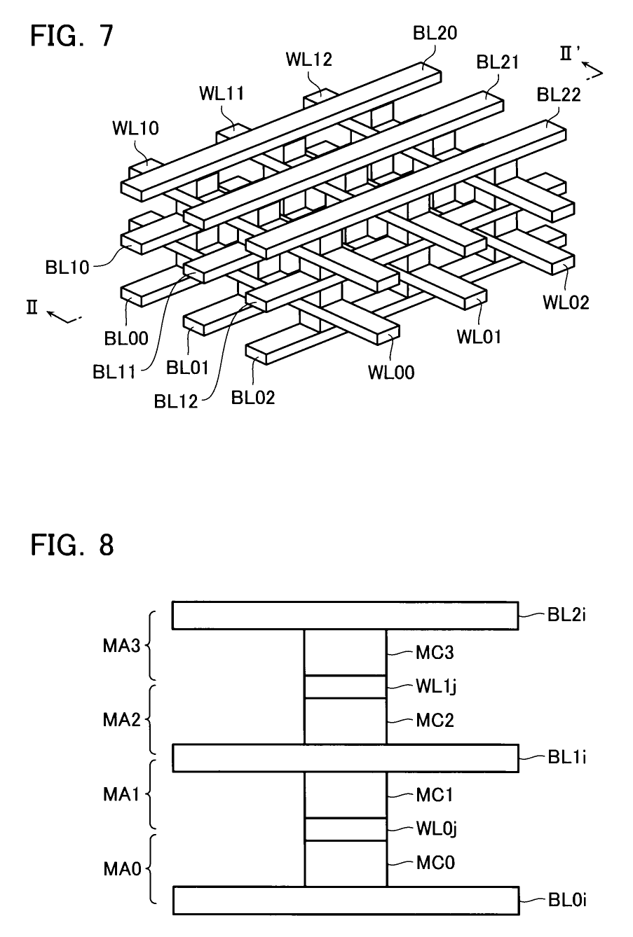

Plural such memory structures described above may be stacked to form a three-dimensional structure as shown in FIG. 7. FIG. 8 is a cross-sectional view showing an II-II′ section in FIG. 7. The shown example relates to a memory cell array of a 4-layer structure having cell array layers MA0-MA3. A word line WL0j is shared by an upper and a lower memory cells MC0, MC1. A bit line BL1i is shared by an upper and a lower memory cells MC1, MC2. A word line WL1j is shared by an upper and a lower memory cells MC2, MC3. In place of the line/cell/line/cell repetition, an interlayer insulator may be interposed as a line/cell/line/interlayer-insulator/line/cell/line between cell array layers.

The memory cell array 1 may be divided into MATs of several memory cell groups. The column control circuit 2 and the row control circuit 3 described above may be provided on a MAT-basis, a sector-basis, or a cell array layer MA-basis or shared by them. Alternatively, they may be shared by plural bit lines BL to reduce the area.

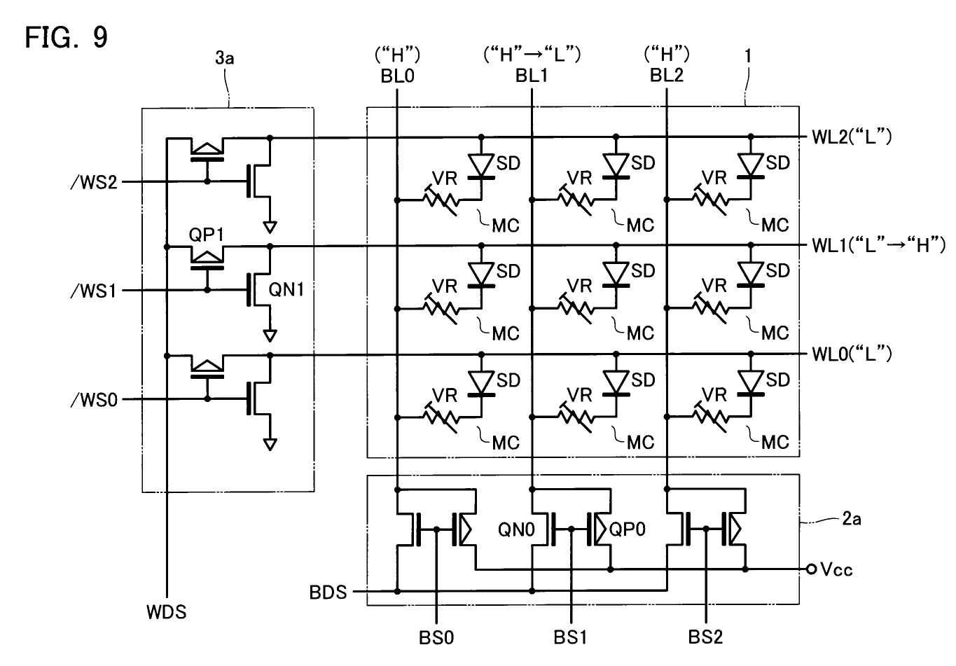

FIG. 9 is a circuit diagram of the memory cell array 1 using a diode SD as the non-ohmic element NO and peripheral circuits thereof. For simplicity, the description advances on the assumption that the memory has a single-layered structure.

In FIG. 9, the diode contained in the memory cell MC has an anode connected to the word line WL and a cathode connected to the bit line BL via the variable resistor VR. Each bit line BL has one end connected to a selection circuit 2a, which is part of the column control circuit 2. Each word line WR has one end connected to a selection circuit 3a, which is part of the row control circuit 3.

The selection circuit 2a includes a selection PMOS transistor QP0 and a selection NMOS transistor QN0, provided at each bit line BL, of which gates and drains are commonly connected. The selection PMOS transistor QP0 has a source connected to a high potential source Vcc. The selection NMOS transistor QN0 has a source connected to a bit-line side drive sense line BDS, which is used to apply a write pulse and supply a detection current at the time of data read. The transistors QP0, QN0 have a common drain connected to the bit line BL, and a common gate supplied with a bit-line selection signal BSi for selecting each bit line BL.

The selection circuit 3a includes a selection PMOS transistor QP1 and a selection NMOS transistor QN1, provided at each word line WL, of which gates and drains are commonly connected. The selection PMOS transistor QP1 has a source connected to a word-line side drive sense line WDS, which is used to apply a write pulse and supply a detection current at the time of data read. The selection NMOS transistor QN1 has a source connected to the low potential source Vss. The transistors QP1, QN1 have a common drain connected to the word line WL and a common gate supplied with a word-line selection signal /WSi for selecting each word line WL.

The example shown above is suitable for selecting the memory cells individually. In contrast, in batch read of data from plural memory cells MC connected to the word line WL1, sense amplifiers are arranged individually for the bit lines BL0-BL2, and the bit lines BL0-BL2 are connected to the sense amplifiers individually by the bit-line selection signal BS via the selection circuit 2a.

The memory cell array 1 may include a diode SD of which polarity is inverted from the circuit shown in FIG. 7 to supply a current flow from the bit line BL to the word line WL.

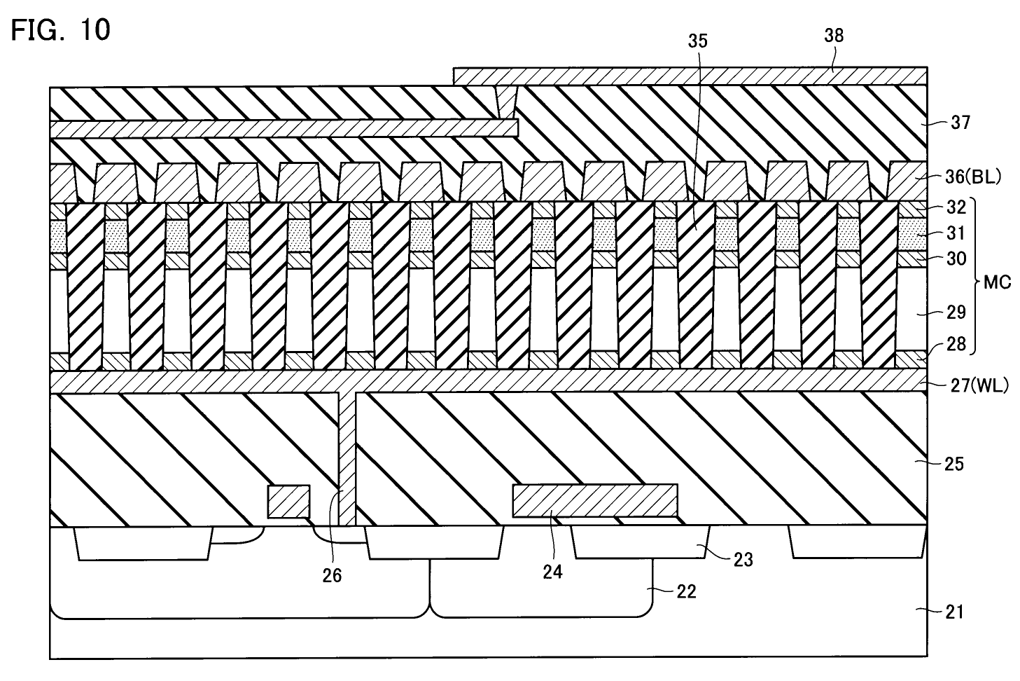

FIG. 10 is a cross-sectional view of the nonvolatile memory including the above-described memory structure in one stage. There is provided a silicon substrate 21 with a well 22 formed therein, on which an impurity-diffused layer 23 and a gate electrode 24 of a transistor contained in a peripheral circuit are formed, on which a first interlayer insulator 25 is deposited. The first interlayer insulator 25 includes a via-hole 26 appropriately formed therethrough to the surface of the silicon substrate 21. On the first interlayer insulator 25, a first metal 27 is formed of a low-resistance metal such as W to form the first line or word line WL in the memory cell array. In an upper layer above the first metal 27, a barrier metal 28 is formed. In a lower layer below the first metal 27, a barrier metal may be formed. These barrier metals may be formed of both or one of Ti and TiN. Above the barrier metal 28, a non-ohmic element 29 such as a diode is formed. On the non-ohmic element 29, a first electrode 30, a variable resistor 31 and a second electrode 32 are formed in this order, thereby configuring a memory cell MC including the barrier metal 28 through the second electrode 32. A barrier metal may be interposed beneath the first electrode 30 and above the second electrode 32. A barrier metal, and an adhesive layer or the like may be interposed below the second electrode 32 and on the first electrode 30. A second interlayer insulator 34 and a third interlayer insulator 35 are buried between the memory cell MC and an adjacent memory cell MC (the second interlayer insulator 34 is not shown in FIG. 10). On the memory cells MC in the memory cell array, a second metal 36 is formed to configure a second line or bit line BL extending in the direction perpendicular to the word line WL. A fourth interlayer insulator 37 and a metal wiring layer 38 are formed thereon to complete the variable resistance memory or nonvolatile memory. A multi-layered structure may be realized by stacking the barrier metal 28 through the second electrode 32 and forming the second and third interlayer insulators 34, 35 between the memory cells MC, repeatedly by the number of layers required.

### [Manufacturing Method in Embodiment]

A method of manufacturing the nonvolatile memory shown in FIG. 10 according to the present embodiment is described next.

First, a FEOL (Front End of Line) process for forming transistors and so forth to form necessary peripheral circuits on the silicon substrate 21 is executed, and then the first interlayer insulator 25 is deposited thereon. The via-hole 26 is formed as well in this step.

Subsequently, the upper layer portion above the first metal 27 is formed.

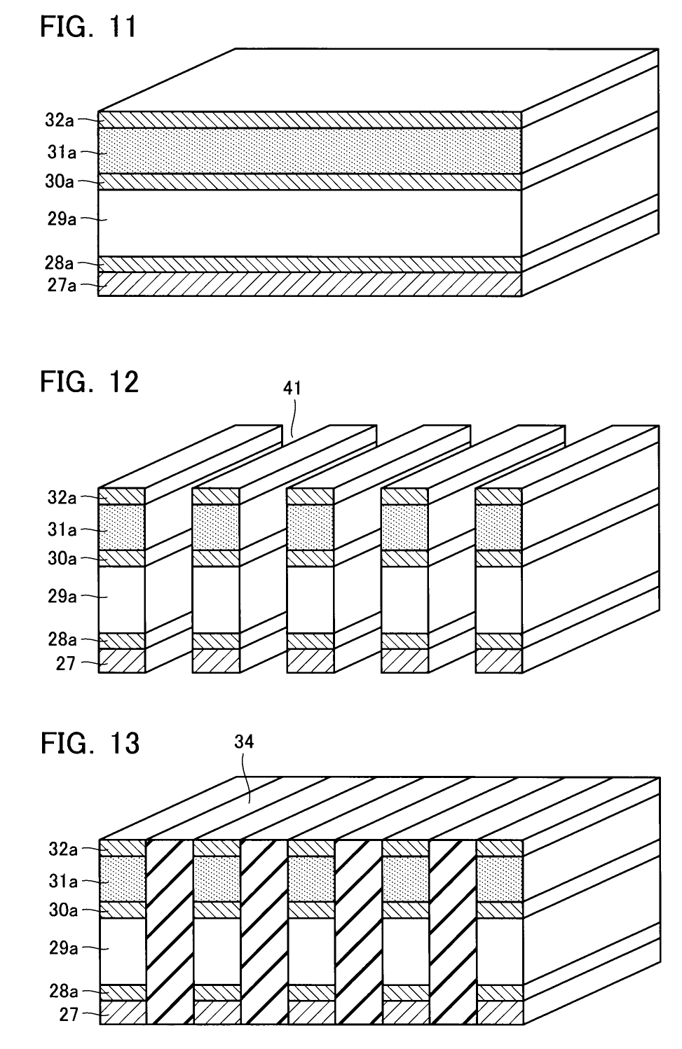

FIGS. 11-16 are perspective views showing steps of forming the upper layer portion in order of step. Referring to FIGS. 11-16 appropriately, processes of forming the upper layer portion are described.

Once the first interlayer insulator 25 and the via-hole 26 are formed as described above, deposition thereon of a layer 27a (first wiring material) turned into the first metal 27 in the memory cell array, then as memory cell materials, formation of a layer 28a turned into the barrier metal 28, deposition of a layer 29a turned into the non-ohmic element 29, deposition of a layer 30a turned into the first electrode 30, deposition of a layer 31a turned into the variable resistor 31, and deposition of a layer 32a turned into the second electrode 32 are executed sequentially. Through the above steps, the stacked body of the upper layer portion shown in FIG. 11 can be formed.

Subsequently, a hard mask such as TEOS, not shown, is formed on the upper surface of the stacked body, and a first anisotropic etching is executed with this mask to form first trenches 41 along the word line WL as shown in FIG. 12 to separate the stacked body.

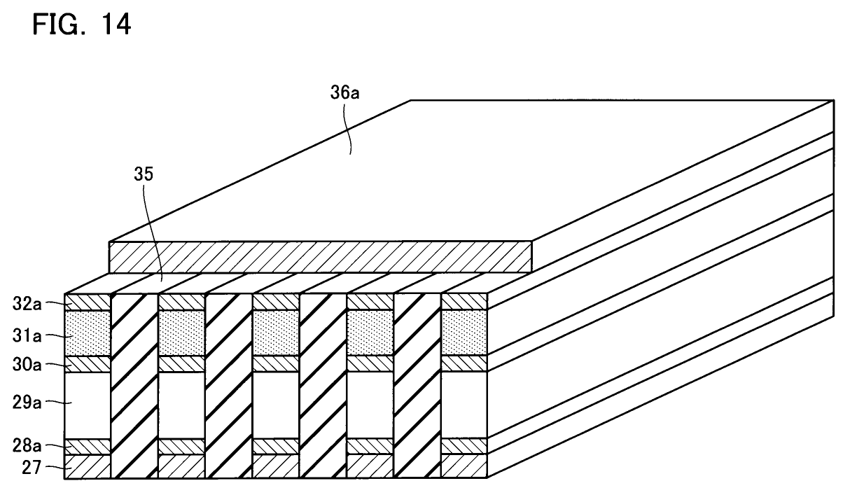

Next, the second interlayer insulator 34 is buried in the trench 41. For the second interlayer insulator 34, a suitable material has excellent insulation, a low capacity and an excellent burial property. Subsequently, a process of CMP or the like is applied in planarization to remove extra portions from the second interlayer insulator 34 and expose the upper electrode 32 to form a block body. The block body after the planarization is shown in FIG. 13.

A layer 36a (second wiring material) such as tungsten turned into the second metal 36 is stacked over the planarized portion of the block body after CMP. The state after this step is shown in FIG. 14.

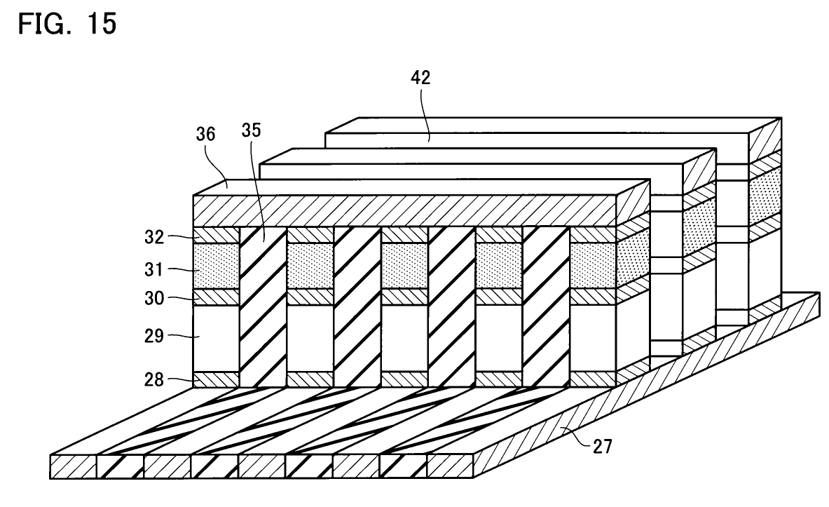

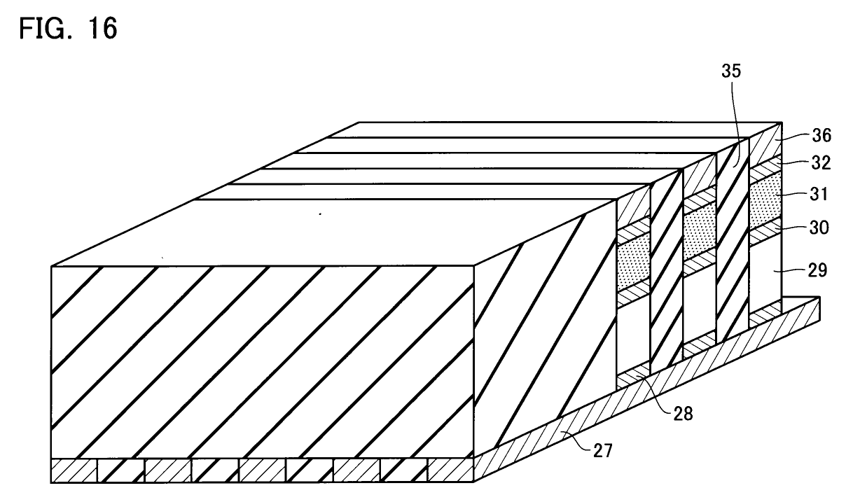

Thereafter, a second etching is executed with L/S in the direction crossing the first etching, thereby forming second trenches 42 along the word line WL orthogonal to the bit line BL as shown in FIG. 15. At the same time, the memory cells MC separated in pillar shapes are formed at cross-points of the bit line BL and the word line WL in a self-aligned manner. Subsequently, the third interlayer insulator 35 is buried and then the third interlayer insulator 35 is planarized, thereby forming the memory array layer of the cross-point type as shown in FIG. 16.

Thus, through stacking flat films and patterning them twice with orthogonal L/S, such the cross-point cells can be formed in a self-aligned manner without any misalignment.

The formation of the above stacked structure can be repeated to complete the memory cell array of the multi-layered cross-point type.

The first trenches 41 and the second trenches 42 may be formed by etching with a hard mask of TEOS, SiO₂, SiN, and amorphous Si as described above or through another method such as a nanoimprint technology.

In the case of the use of the nanoimprint technology, first, a low-viscosity liquid resist is dropped onto the upper surface of the stacked body and the block body and then a template of quartz is pressed thereon under an extremely small force. The template has a plurality of parallel trenches formed on the lower surface thereof. The template can be processed through a conventional method such as photolithography and can be finely processed with an L/S of the order of 10 nm. Accordingly, the template can be used to create a fine cross point structure. The template is pressed onto the stacked body and the block body to bury the resist inside the trenches with no gaps left. Next, ultraviolet rays are applied to the template to expose the resist to light to facilitate bridging of the resist. Then, the template is removed to form a resist pattern. The step of dropping the resist through the step of exposing the resist to light are repeated in a step-and-repeat manner to form the resist pattern over the stacked body and the block body.

### Other Embodiments

The present invention is not particularly limited to the structure of the memory cell but rather can be applied to various multi-layered memories of the cross point type such as a phase change memory element, an MRAM element, a PFRAM, and a ReRAM.

What is claimed is:

1. A method of manufacturing nonvolatile semiconductor memory devices, comprising:
forming a first wiring material;
stacking memory cell materials on said first wiring material, which configure memory cells each including a variable resistor operative to nonvolatilely store information in accordance with a variation in resistance;
forming a plurality of first parallel trenches in said first wiring material and said stacked memory cell materials, said first trenches extending in a first direction, thereby forming first lines extending in said first direction and memory cell materials self-aligned with said first lines and separated by said first trenches;
burying an interlayer insulator in said first trenches to form a block body;
stacking a second wiring material on said block body; and
forming a plurality of second parallel trenches in said block body with said second wiring material stacked thereon, said second trenches extending in a second direction crossing said first direction and having a depth reaching the upper surface of said first wiring material, thereby forming second lines extending in said second direction and memory cells self-aligned with said second lines and separated by said first and second trenches.

2. The method of manufacturing nonvolatile semiconductor memory devices according to claim 1, wherein said first and second trenches are formed by etching with a mask of line-and-space formed through a nanoimprint technology.

3. The method of manufacturing nonvolatile semiconductor memory devices according to claim 1, wherein said first and second trenches are formed by etching with a mask of line-and-space formed of a hard mask material.

4. The method of manufacturing nonvolatile semiconductor memory devices according to claim 1, wherein said first and second wiring materials are any one of W, WSi, NiSi, and CoSi.

5. The method of manufacturing nonvolatile semiconductor memory devices according to claim 3, wherein said hard mask material is any one of TEOS, SiO₂, SiN, and amorphous Si.

6. The method of manufacturing nonvolatile semiconductor memory devices according to claim 1, wherein
said memory cell further includes a non-ohmic element serially connected to said variable resistor,
the step of stacking memory cell materials includes sequentially depositing a layer turned into a barrier metal of said memory cell, a layer turned into said non-ohmic element, a layer turned into a first electrode, a layer turned into said variable resistor, and a layer turned into a second electrode.

7. The method of manufacturing nonvolatile semiconductor memory devices according to claim 6, wherein said variable resister comprises a composite compound containing cations of a transition element.

8. The method of manufacturing nonvolatile semiconductor memory devices according to claim 6, wherein said non-ohmic element is a diode.

9. A method of manufacturing nonvolatile semiconductor memory devices, comprising:
forming a first interlayer insulator on a semiconductor substrate;
forming a first wiring material on said first interlayer insulator;
stacking memory cell materials on said first wiring material, which configure memory cells each including a variable resistor operative to nonvolatilely store information in accordance with a variation in resistance;
forming a plurality of first parallel trenches in said first wiring material and said stacked memory cell materials, said first trenches extending in a first direction, thereby forming first lines extending in said first direction and memory cell materials self-aligned with said first lines and separated by said first trenches;
burying a second interlayer insulator in said first trenches to form a block body and planarizing the surface of said block body to expose said memory cell materials;
stacking a second wiring material on said planarized block body;
forming a plurality of second parallel trenches in said block body with said second wiring material stacked thereon, said second trenches extending in a second direction crossing said first direction and having a depth reaching the upper surface of said first wiring material, thereby forming second lines extending in said second direction and memory cells self-aligned with said second lines and separated by said first and second trenches; and
burying a third interlayer insulator in said second trenches.

10. The method of manufacturing nonvolatile semiconductor memory devices according to claim 9, further comprising:
forming a peripheral circuit on said semiconductor substrate; and
forming a via-line through said first interlayer insulator to connect said peripheral circuit to said first and second lines.

11. The method of manufacturing nonvolatile semiconductor memory devices according to claim 9, wherein said first and second trenches are formed by etching with a mask of line-and-space formed through a nanoimprint technology.

12. The method of manufacturing nonvolatile semiconductor memory devices according to claim 10, wherein said first and second trenches are formed by etching with a mask of line-and-space formed through a nanoimprint technology.

13. The method of manufacturing nonvolatile semiconductor memory devices according to claim 9, wherein said first and second trenches are formed by etching with a mask of line-and-space formed of a hard mask material.

14. The method of manufacturing nonvolatile semiconductor memory devices according to claim 10, wherein said first and second trenches are formed by etching with a mask of line-and-space formed of a hard mask material.

15. The method of manufacturing nonvolatile semiconductor memory devices according to claim 9, wherein
said memory cell further includes a non-ohmic element serially connected to said variable resistor,
the step of stacking memory cell materials includes sequentially depositing a layer turned into a barrier metal of said memory cell, a layer turned into said non-ohmic element, a layer turned into a first electrode, a layer turned into said variable resistor, and a layer turned into a second electrode.

16. A method of manufacturing nonvolatile semiconductor memory devices, comprising:
forming a first wiring material;
sequentially depositing a layer turned into a barrier metal, a layer turned into a non-ohmic element, a layer turned into a first electrode, a layer turned into a variable resistor, and a layer turned into a second electrode as memory cell materials on said first wiring material;
forming a plurality of first parallel trenches in said first wiring material and said stacked memory cell materials, said first trenches extending in a first direction, thereby forming first lines extending in said first direction and memory cell materials self-aligned with said first lines and separated by said first trenches;
burying an interlayer insulator in said first trenches to form a block body;
stacking a second wiring material on said block body; and
forming a plurality of second parallel trenches in said block body with said second wiring material stacked thereon, said second trenches extending in a second direction crossing said first direction and having a depth reaching the upper surface of said first wiring material, thereby forming second lines extending in said second direction and memory cells self-aligned with said second lines and separated by said first and second trenches.

17. The method of manufacturing nonvolatile semiconductor memory devices according to claim 16, wherein said first and second trenches are formed by etching with a mask of line-and-space formed through a nanoimprint technology.

18. The method of manufacturing nonvolatile semiconductor memory devices according to claim 16, wherein said first and second trenches are formed by etching with a mask of line-and-space formed of a hard mask material.

19. The method of manufacturing nonvolatile semiconductor memory devices according to claim 16, wherein said variable resistor comprises a composite compound containing cations of a transition element.

20. The method of manufacturing nonvolatile semiconductor memory devices according to claim 16, wherein said non-ohmic element is a diode.
